(19) United States
(12) Patent Application Publication
(10) Pub. No.: US 2024/0096817 A1
(43) Pub. Date: Mar. 21, 2024

(54) ON-CHIP HYBRID ELECTROMAGNETIC INTERFERENCE (EMI) SHIELDING WITH THERMAL MITIGATION

(71) Applicant: QUALCOMM Incorporated, San Diego, CA (US)

(72) Inventors: Ranadeep DUTTA, Del Mar, CA (US); Jonghae KIM, San Diego, CA (US); Je-Hsiung LAN, San Diego, CA (US)

(21) Appl. No.: 17/932,788

(22) Filed: Sep. 16, 2022

(51) Int. Cl. H01L 23/552; H01L 21/48; H01L 23/00; H01L 23/373; H01L 23/498; H01L 23/528; H01L 23/66; H01Q 1/02; H01Q 1/22; H01Q 3/36; H01Q 9/04; H01Q 21/06

(52) U.S. Cl. CPC H01L 23/552; H01L 21/4853; H01L 23/3736; H01L 23/49838; H01L 23/5283; H01L 23/5286; H01L 23/66; H01L 24/08; H01Q 1/02; H01Q 1/2283; H01Q 3/36; H01Q 9/0414; H01Q 21/065; H01L 23/49816; H01L 2223/6616; H01L 2223/6644; H01L 2223/6677; H01L 2224/08225; H01L 2924/14215; H01L 2924/3025; H01L 2924/351

(57) ABSTRACT

Disclosed are techniques for on-chip electromagnetic interference (EMI) shielding. In an aspect, an integrated circuit includes a noise-sensitive device, a first metallization layer disposed on a first side of the noise-sensitive device, wherein the first metallization layer includes a plurality of conductive routing layers, and wherein conductive routing within the plurality of conductive routing layers is configured as a first side of an on-chip electromagnetic interference (EMI) shield around the first side of the noise-sensitive device, and a second metallization layer disposed on a second side of the noise-sensitive device opposite the first side of the noise-sensitive device, wherein the second metallization layer includes one or more conductive routing layers, and wherein conductive routing within the one or more conductive routing layers is configured as a second side of the on-chip EMI shield around the second side of the noise-sensitive device.

### BACKGROUND OF THE DISCLOSURE

### 1. Field of the Disclosure

Aspects of the disclosure relate generally to semiconductor fabrication, and more specifically, to on-chip electromagnetic interference (EMI) shielding.

### 2. Description of the Related Art

An integrated circuit (also referred to as an “IC,” a “chip,” a “microchip,” or the like) is a set of electronic circuits on a small piece of semiconductor material, usually silicon. Integrated circuits are now used in virtually all electronic devices. Computers (e.g., desktop computers, laptop computers, tablet computers, etc.), mobile phones, and other home appliances all include integrated circuits.

An integrated circuit that transmits and receives radio waves is referred to as a radio frequency integrated circuit (RFIC). RFICs are found in portable telephones, cellphones, Wi-Fi devices, Bluetooth devices, Global Positioning System (GPS) receivers, wireless routers, wireless base stations, satellite transceivers, and microwave equipment. For example, modem smartphones include one or more RFICs that handle cellular voice and data communication, GPS, Wi-Fi, and Bluetooth functionality.

Integrated circuits utilize small voltages and currents that an electromagnetic field can easily disrupt. Such electromagnetic interference (EMI), or radio frequency interference (RFI), is a problem for most integrated circuits, and especially RFICs, since it can decrease the performance of the integrated circuits or even cause them to fail. EMI shielding is a technique of creating a barrier that prevents leakage of strong electromagnetic fields that can interfere with sensitive integrated circuits. They can be installed to isolate the electromagnetic field source or as an enclosure on or around the electronic device that needs protection.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an integrated circuit includes a noise-sensitive device; a first metallization layer disposed on a first side of the noise-sensitive device, wherein the first metallization layer includes a plurality of conductive routing layers, and wherein conductive routing within the plurality of conductive routing layers is configured as a first side of an on-chip electromagnetic interference (EMI) shield around the first side of the noise-sensitive device; and a second metallization layer disposed on a second side of the noise-sensitive device opposite the first side of the noise-sensitive device, wherein the second metallization layer includes one or more conductive routing layers, wherein conductive routing within the one or more conductive routing layers is configured as a second side of the on-chip EMI shield around the second side of the noise-sensitive device, and wherein the conductive routing within the one or more conductive routing layers is coupled to the conductive routing within the plurality of conductive routing layers.

In an aspect, a method of manufacturing an integrated circuit includes coupling a first metallization layer to a first side of a noise-sensitive device, wherein the first metallization layer includes a plurality of conductive routing layers, and wherein conductive routing within the plurality of conductive routing layers is configured as a first side of an on-chip electromagnetic interference (EMI) shield around the first side of the noise-sensitive device; and coupling a second metallization layer to a second side of the noise-sensitive device opposite the first side of the noise-sensitive device, wherein the second metallization layer includes one or more conductive routing layers, wherein conductive routing within the one or more conductive routing layers is configured as a second side of the on-chip EMI shield around the second side of the noise-sensitive device, and wherein the conductive routing within the one or more conductive routing layers is coupled to the conductive routing within the plurality of conductive routing layers.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a comparison of package-level and board level electromagnetic interference (EMI) shielding.

FIG. 2 is a diagram illustrating a side view of an example radio frequency integrated circuit (RFIC) with chip-level EMI shielding, according to aspects of the disclosure.

FIG. 3 is a diagram illustrating atop view and a cross section of an example on-chip EMI shield, according to aspects of the disclosure.

FIG. 4 is a diagram illustrating differences between an RFIC utilizing conventional EMI shielding and an RFIC utilizing on-chip EMI shielding, according to aspects of the disclosure.

FIG. 5 is a diagram illustrating a top view and a cross section of an example on-chip EMI shield, according to aspects of the disclosure.

FIG. 6 is a diagram illustrating differences between an RFIC utilizing conventional EMI shielding and an RFIC utilizing on-chip EMI shielding with double-sided metallization, according to aspects of the disclosure.

FIG. 7 is another diagram illustrating differences between an RFIC utilizing conventional EMI shielding and an RFIC utilizing on-chip EMI shielding with double-sided metallization, according to aspects of the disclosure.

FIG. 8 illustrates a cross section of an example integrated circuit, according to aspects of the disclosure.

FIG. 9 illustrates an example method of manufacturing an integrated circuit, according to aspects of the disclosure.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

Integrated circuits utilize small voltages and currents that an electromagnetic field can easily disrupt. Such electromagnetic interference (EMI), or radio frequency interference (RFI), is a problem for most integrated circuits, since it can decrease the performance of the integrated circuits or even cause them to fail. EMI shielding is a technique of creating a barrier that prevents leakage of strong electromagnetic fields that can interfere with sensitive integrated circuits. They can be installed to isolate the electromagnetic field source or as an enclosure on or around the electronic device that needs protection.

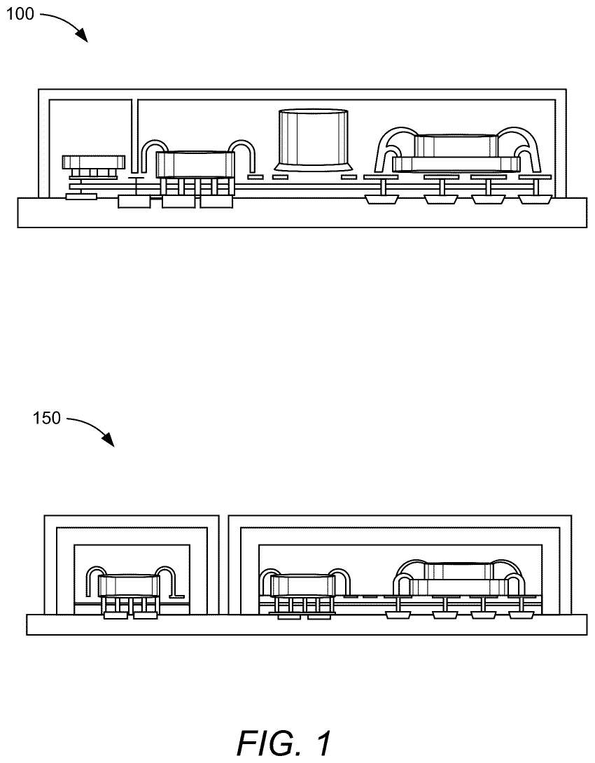

Currently, EMI shielding is provided at the package-level or the circuit board level. FIG. 1 illustrates a comparison of package-level and board level EMI shielding. Specifically, diagram 100 illustrates an example of package-level EMI shielding and diagram 150 illustrates an example of board level EMI shielding.

There are issues with package-level and board level EMI shielding. For example, noise-sensitive devices integrated on a radio frequency integrated circuit (RFIC), such as the low noise amplifier (LNA), power amplifier (PA), etc., need EMI shielding from the external environment. These devices inadequately shielded from external EMI by package-level or board level EMI shielding due to the radiation sidelobe from the antenna directly above them. As another example, circulating currents on the module enclosure may cause spurious emissions that are not blocked by package-level or board level EMI shielding. As yet another example, there may be noise coupling between the LNA and PA, for example, if they share a common ground at the chip level. Package-level or board level EMI shielding cannot block such noise coupling.

As such, there is a need for EMI shielding at the chip level. This is not a process of record (POR), as EMI is not considered at the chip design stage.

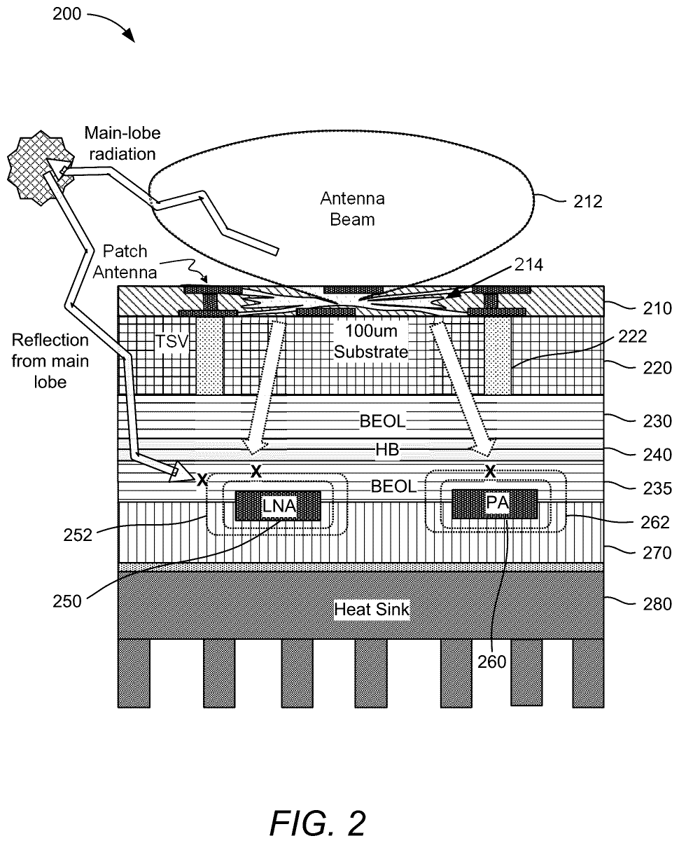

FIG. 2 is a diagram 200 illustrating a side view of an example RFIC with chip-level EMI shielding, according to aspects of the disclosure. As shown in FIG. 2, a patch antenna 210 is mounted to a substrate 220. A patch antenna, such as patch antenna 210, is a low profile antenna that can be mounted on a surface. It consists of a planar geometrical (e.g., rectangular, circular, triangular, etc.) sheet, or “patch,” of metal, mounted over a larger sheet of metal called a ground plane. The two metal sheets together form a resonant piece of microstrip transmission line with a length of approximately one-half the wavelength of the radio waves the patch antenna 210 is designed to transmit/receive.

The patch antenna 210 is connected (coupled) to a first back end of line (BEOL) layer 230 by one or more through silicon vias (TSVs) 222. BEOL is the second portion of IC fabrication in which individual devices (e.g., transistors, capacitors, resistors, etc.) are interconnected with metal routing (e.g., wiring) on the substrate 220. BEOL generally begins when the first layer of metal (first routing layer) is deposited on the substrate 220, and includes contacts, insulating layers (dielectrics), metal levels, and bonding sites for chip-to-package connections. In modern integrated circuits, a BEOL layer, such as BEOL layer 230, may comprise more than 10 metal routing layers separated by insulating layers (dielectric layers).

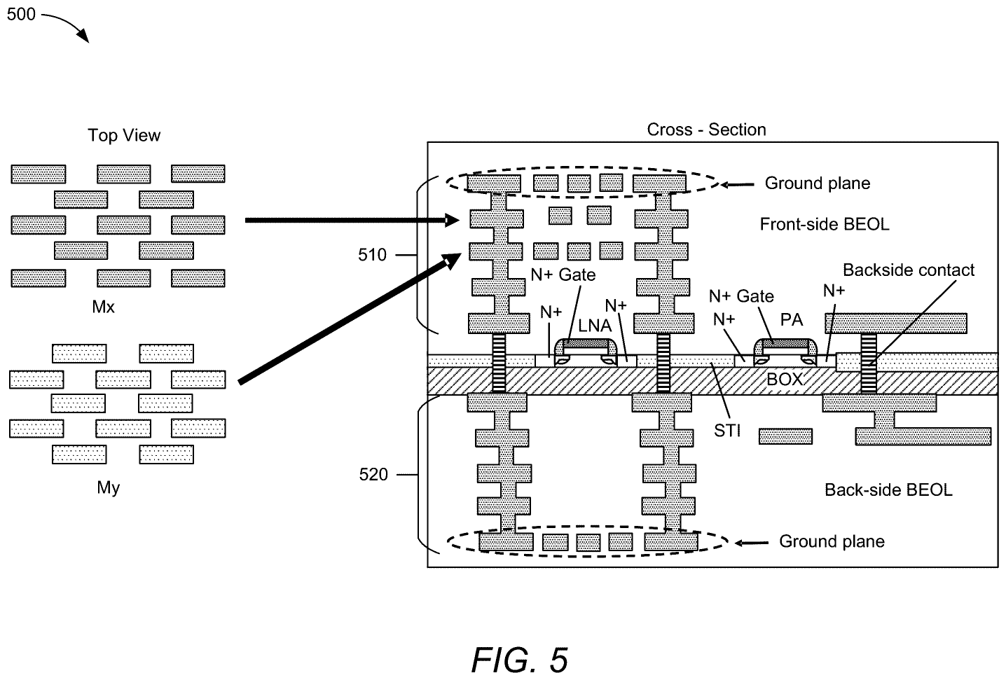

The first BEOL layer 230 is connected (coupled) to a second BEOL layer 235 by a hybrid bond (HB) layer 240. Connected (coupled) to the second BEOL layer 235 are two noise-sensitive devices, illustrated as an LNA 250 and a PA 260. As will be appreciated, there may be more or fewer than the two illustrated noise-sensitive devices, and the noise-sensitive devices may be other types of devices than the illustrated LNA 250 and the PA 260. Surrounding the LNA 250 is on-chip EMI shielding 252 and surrounding the PA 260 is on-chip EMI shielding 262, each represented as concentric dashed boxes. This on-chip EMI shielding will be discussed in more detail below. The LNA 250 and PA 260 are embedded in an interposer layer 270, and the entire RFIC is mounted to a heat sink 280. Note that the interposer lay 2709 may instead be another BEOL layer, as described below with reference to FIG. 5.

As shown in FIG. 2, the patch antenna 210 is mounted on the substrate 220 (a layer of silicon) directly above noise sensitive circuits (e.g., LNA 250 and PA 260). The patch antenna 210 radiates an antenna beam with a main lobe 212 and multiple (e.g., two) sidelobes (one of which is indicated by reference number 214). The radiation from the main lobe 212 may reflect off one or more objects in the environment and back towards the LNA 250 and the PA 260, as shown by the arrows. The radiation from the side lobes 214 may be directed towards the LNA 250 and the PA 260, as shown by the dashed arrows. The radiation from the main lobe 212 and the side lobes 214 may have a severe EMI impact on the LNA 250, the PA 260, and/or other noise-sensitive circuits. For example, the LNA 250 may be only approximately 500 microns (μm) away from the patch antenna 210. 500 μm is approximately 0.05·λ for f=30 GHz. However, as described further below, because of the on-chip EMI shielding 252 and 262, the affects of this radiation are blocked or at least significantly reduced, as indicated by the “X” at the end of each arrow terminating at the on-chip EMI shielding 252 and 262.

At a high level, the on-chip EMI shielding 252 is a Faraday cage (a continuous mesh of conductive material) implemented by BEOL routing layers in the second BEOL layer 235. The resulting metal mesh shielding structure largely cancels EMI from the antenna sidelobes 214 and reflections of the main lobe 212. Shielding on multiple layers further suppresses EMI. Further, the electrically grounded heat sink 280 suppresses eddy currents on the enclosure.

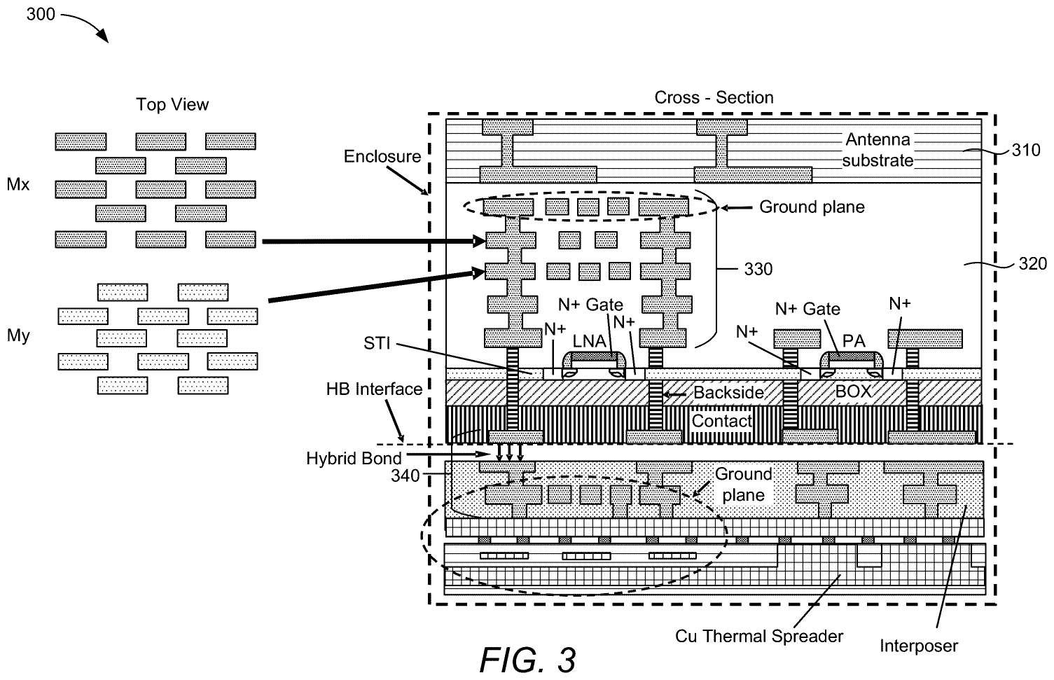

FIG. 3 is a diagram 300 illustrating a top view and a cross section of an example on-chip EMI shield, according to aspects of the disclosure. The on-chip EMI shielding illustrated in FIG. 3 utilizes front-side BEOL, back-side hybrid bonding, and a thermal spreader. The circuit shown in FIG. 3 may be, for example, a complementary metal-oxide-semiconductor (CMOS).

As shown in FIG. 3, an antenna substrate 310 (e.g., patch antenna 210 and substrate 220 in FIG. 2) is mounted to a front-side BEOL layer 320. The antenna substrate 310 may be separated from the front-side BEOL layer 320 by a substrate (not shown), as in the RFIC of FIG. 2. In the example of FIG. 3, an LNA is surrounded by front-side on-chip EMI shielding 330 within the front-side BEOL layer 320 and back-side on-chip EMI shielding 340 within the interposer layer. An interposer is an electrical interface routing between one connection and another. The purpose of an interposer is to spread a connection to a wider pitch or to reroute a connection to a different connection.

The front-side on-chip EMI shielding 330 and back-side on-chip EMI shielding 340 are composed of multiple metal (shielding) layers interspersed within the front-side BEOL layer 320 and the interposer, respectively. The metal layers of the front-side on-chip EMI shielding 330 and the back-side on-chip EMI shielding 340 form a stacked metal ring (shielding screen) around the LNA with staggered offsets at different levels (as shown in the top view) to optimize shielding. Only a few metal layers (e.g., two or three) may be needed for the front-side on-chip EMI shielding 330, and the remaining layers may be used for the interconnects to and from the LNA (or other component being shielded). In the example of FIG. 3, only two metal layers (in addition to the ground plane) are used for the front-side on-chip EMI shielding 330. For simplicity, the interconnect layers below are not shown on the cross-section. The stacked metal layers improve EMI shielding by forming a Faraday cage around the LNA. Specifically, the on-chip EMI shielding illustrated in FIG. 3 can provide an EMI improvement greater than 20 decibels (dB) over current techniques.

As shown in FIG. 3, the first, or top, metal layer of the front-side on-chip EMI shielding 330 may be the ground plane of the front-side on-chip EMI shielding 330. Note that the term “ground plane” has two different meanings in separate areas of electrical engineering. With respect to antennas, a ground plane is a conductive surface larger than the wavelength that is connected to the transmitter's ground wire and serves as a reflecting surface for radio waves (as mentioned above with respect to FIG. 2). In integrated circuits, a ground plane is a large area of conductive metal on the circuit that is connected (coupled) to the power supply ground terminal and serves as a return path for current from different components on the circuit. The hybrid bond (HB) between the front-side on-chip EMI shielding 330 and the back-side on-chip EMI shielding 340 enables a second ground plane on the backside.

In the example of FIG. 3, an electrically grounded copper (Cu) thermal spreader on the back side provides thermal mitigation and added EMI shielding. A heat spreader has a large, flat surface that allows heat to be dissipated over a large surface area. This surface is often compressed against another large flat surface (e.g., a chassis or backplane), and heat passes from a small heat spreader out to the larger surface. A heat spreader is often used for systems that require low profile solutions or that are expected to operate under extreme shock and vibration. The thermal spreader also forms an electrical ground (the ground plane) to minimize circulating currents in the enclosure. Note that although not shown, a heat sink may also be used even when a thermal spreader is present, as a thermal spreader is a more localized, intermediate thermal mitigator and a heat sink is a more global thermal mitigator.

There are considerations related to aperture control (i.e., the size of the openings between routing segments of the metal routing of the BEOL routing layers) versus wavelength. For example, the optimal design may be less than approximately 0.01 k. However, the design can be tuned based on the application (e.g., frequency band). In addition, the amount of shielding may depend on the sensitivity of the circuit being protected. For example, a PA may not need as much shielding as an LNA.

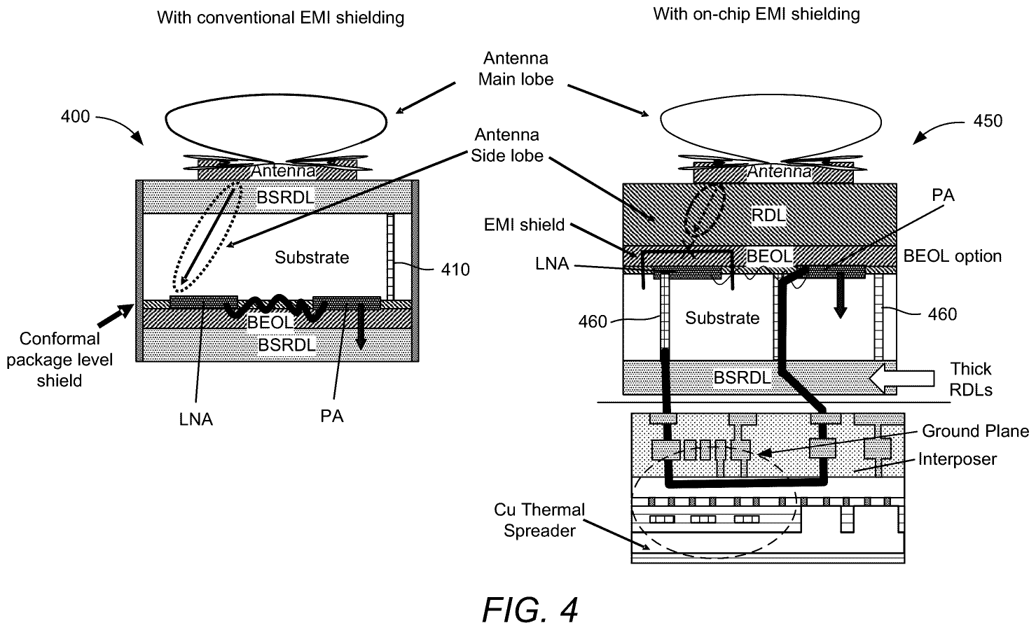

FIG. 4 is a diagram illustrating differences between an RFIC 400 utilizing conventional EMI shielding and an RFIC 450 utilizing on-chip EMI shielding, according to aspects of the disclosure. As shown in FIG. 4, the RFIC 400 is composed of an antenna (e.g., a patch antenna) mounted to a back-side redistribution layer (BSRDL). A redistribution layer (RDL) is the conductive metal interconnects that electrically connect one part of a semiconductor package to another. A TSV 410 through a substrate between the antenna and the LNA and PA connects the antenna to the LNA and PA. The LNA and PA are connected (coupled) to a BEOL layer, which is in turn connected (coupled) to a second BSRDL. The connectivity pathway between the LNA and the PA and to the BSRDL is shown by a heavy black line/arrow. Around the sides of the RFIC 400 is a conformal package-level shield. As shown in FIG. 4, the conformal package-level shield does not block the radiation from the antenna side lobes.

In contrast, the RFIC 450 is composed of an antenna (e.g., a patch antenna) mounted to an RDL, which is in turn connected (coupled) a BEOL layer. An LNA and PA are connected (coupled) to the BEOL layer, and chip-level EMI shielding within the BEOL layer forms a portion of the on-chip EMI shielding for the RFIC 450, as described above with reference to FIG. 3. A TSV 460 through a substrate between a BSRDL and the LNA and the PA connects the LNA and PA to the BSRDL. The BSRDL is connected (coupled) to an interposer via a hybrid bond. As discussed above with reference to FIG. 3, metallization in the interposer forms the remainder of the on-chip EMI shielding. The interposer is then connected (coupled) to a thermal spreader (e.g., of copper). The connectivity pathway between the LNA and the PA through the BSRDL and thermal spreader is shown by a heavy black line/arrow. As shown in FIG. 4, the on-chip EMI shielding blocks (as shown by the “X”) the radiation from the antenna side lobes.

The following table summarizes the differences between an RFIC utilizing conventional EMI shielding (e.g., RFIC 400) and an RFIC utilizing on-chip EMI shielding (e.g., RFIC 450).

TABLE 1

| With conventional EMI | |
|---|---|
| shielding | With on-chip EMI shielding |
| Antenna facing back side of RF | Antenna facing front side of RF front |
| front end die | end die |
| No EMI shield on antenna side | EMI shield using BEOL metal protects |
| | from EMI from outside (antenna side) |
| No EMI shield on back side | EMI shield completed on back side with |
| | routing layers of hybrid-bonded |
| | interposer or back side BEOL |
| LNA and PA share ground plane | LNA and PA share a common ground at |
| at chip level | the interposer (far removed from the |
| | chip), which reduces noise coupling |
| No thermal spreader | Thermal spreader connected to back |
| | side of chip via the interposer |
| Heat sink not electrically | Thermal spreader electrically grounded |
| grounded | via the interposer, which suppresses |
| | eddy current on the enclosure |
| Conformal package-level | None. Not needed due to chip-level |
| shielding to protect from | shielding |
| reflected antenna radiation | |

FIG. 5 is a diagram 500 illustrating a top view and a cross section of an example on-chip EMI shield, according to aspects of the disclosure. In contrast to the on-chip EMI shielding illustrated in FIG. 3, the on-chip EMI shielding illustrated in FIG. 5 utilizes double-sided metallization (back side contact). The circuit shown in FIG. 5 may be, for example, a CMOS.

In the example of FIG. 5, an LNA is surrounded by front-side on-chip EMI shielding 510 within a front-side BEOL layer and back-side on-chip EMI shielding 520 within a back-side BEOL layer. The front-side on-chip EMI shielding 510 and back-side on-chip EMI shielding 520 are composed of multiple metal (shielding) layers interspersed within the front-side BEOL layer and the back-side BEOL layer, respectively. The metal layers of the front-side on-chip EMI shielding 510 and the back-side on-chip EMI shielding 520 form a stacked metal ring (shielding screen) around the LNA with staggered offsets at different levels (as shown in the top view) to optimize shielding. Only a few metal layers (e.g., two or three) may be needed for the front-side on-chip EMI shielding 510, and the remaining layers may be used for the interconnects to and from the LNA (or other component being shielded). In the example of FIG. 5, only two metal layers (in addition to the ground plane) are used for the front-side on-chip EMI shielding 510. For simplicity, the interconnect layers below are not shown on the cross-section. The stacked metal layers improve EMI shielding by forming a Faraday cage around the LNA. Specifically, the on-chip EMI shielding illustrated in FIG. 5 can provide an EMI improvement greater than 20 decibels (dB) over current techniques.

As shown in FIG. 5, the first, or top, metal layer of both the front-side on-chip EMI shielding 510 and the back-side on-chip EMI shielding 520 may be the ground plane of the front-side on-chip EMI shielding 510 and the back-side on-chip EMI shielding 520, respectively. The buried oxide (BOX) (which separates the top thin device silicon from the silicon substrate of a silicon-on-insulator (SOI) wafer) between the front-side on-chip EMI shielding 510 and the back-side on-chip EMI shielding 520 enables there to be the second ground plane on the backside.

There are considerations related to aperture control versus wavelength. For example, the optimal design may be less than approximately 0.01 k. However, the design can be tuned based on the application (e.g., frequency band). In addition, the amount of shielding may depend on the sensitivity of the circuit being protected. For example, a PA may not need as much shielding as an LNA.

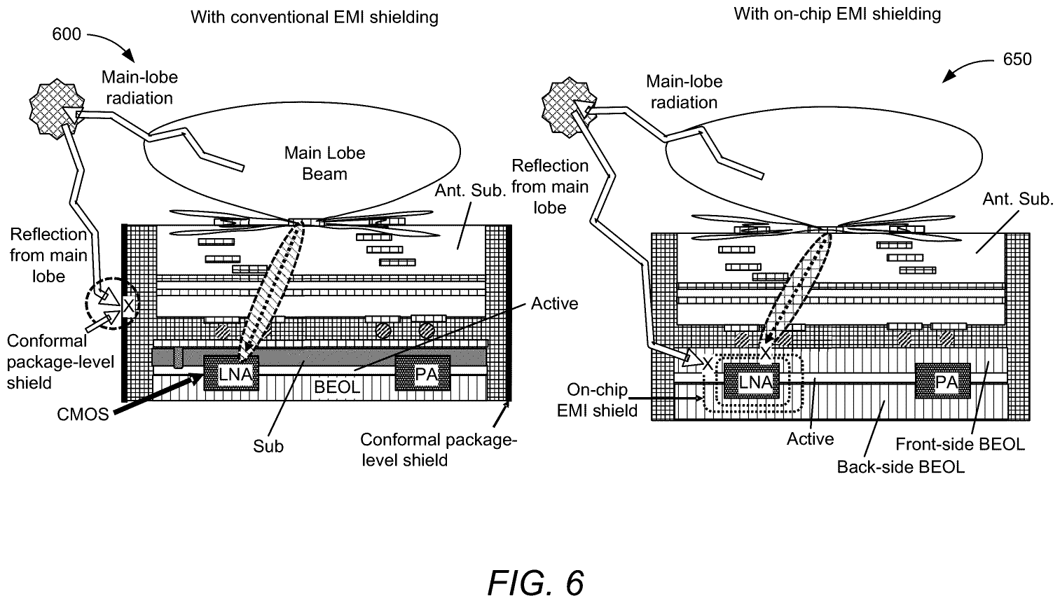

FIG. 6 is a diagram illustrating differences between an RFIC 600 utilizing conventional EMI shielding and an RFIC 650 utilizing on-chip EMI shielding with double-sided metallization, according to aspects of the disclosure. As shown in FIG. 6, the RFIC 600 is composed of an antenna substrate (e.g., a patch antenna, abbreviated in the figure as “Ant. Sub.”) mounted above an LNA and a PA. Around the sides of the RFIC 600 is a conformal package-level shield. As shown in FIG. 6, the conformal package-level shield blocks radiation from reflections of the main lobe antenna beam (as represented by the “X”), but does not block radiation from the antenna side lobes.

In contrast, the LNA of the RFIC 650 is shielded by chip-level EMI shielding (represented as dashed round-corner boxes) within front-side and back-side BEOL layers, as described above with reference to FIG. 5. As shown in FIG. 6, the on-chip EMI shielding blocks both the radiation from the antenna main lobe and the radiation from the antenna side lobes (as represented by the “X”). The on-chip EMI shielding eliminates the need for the conformal package-level shielding.

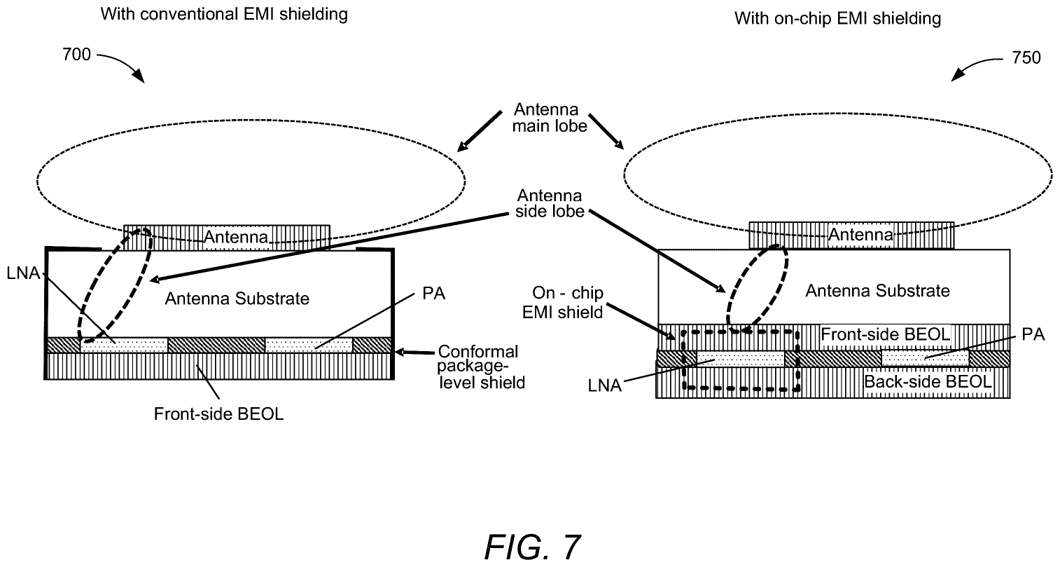

FIG. 7 is another diagram illustrating differences between an RFIC 700 utilizing conventional EMI shielding and an RFIC 750 utilizing on-chip EMI shielding with double-sided metallization, according to aspects of the disclosure. As shown in FIG. 7, the RFIC 700 includes an antenna (e.g., a patch antenna) and antenna substrate mounted above an LNA and a PA. Around the sides of the RFIC 700 is a conformal package-level shield. As shown in FIG. 7, the conformal package-level shield does not block radiation from the antenna side lobes.

In contrast, the LNA of the RFIC 750 are shielded by chip-level EMI shielding (represented as a dashed box) within front-side and back-side BEOL layers, as described above with reference to FIG. 5. As shown in FIG. 7, the on-chip EMI shielding blocks and the radiation from the antenna side lobes. The on-chip EMI shielding eliminates the need for the conformal package-level shielding.

The following table summarizes the differences between an RFIC utilizing conventional EMI shielding (e.g., RFIC 600, RFIC 700) and an RFIC utilizing on-chip EMI shielding with double-sided metallization (e.g., RFIC 650, RFIC 750).

TABLE 2

| With conventional EMI shielding | With on-chip EMI shielding |
|---|---|
| Antenna facing back side of RF | Antenna facing front side of RF |
| front end die | front end die |
| No EMI shield on antenna side | EMI shielding protects from EMI |
| | from outside (antenna side) |
| No EMI shield on back side | EMI shield completed on both sides |
| | with BEOL interspersed layout |
| Conformal package-level shielding | None. Not needed due to chip-level |
| to protect from reflected antenna | shielding |
| radiation | |

As will be appreciated, while the foregoing on-chip EMI shielding examples only illustrate the LNA being shielded, as will be appreciated, the PA could also, or alternatively, be shielded by on-chip EMI shielding. In addition, while the foregoing examples illustrate an LNA and a PA, the techniques described herein apply equally to other noise-sensitive devices. Similarly, while the foregoing examples illustrate an LNA and a PA, the two devices may be a single device, more than two devices, both LNAs, both PAs, and the like.

As will be appreciated, the on-chip EMI shielding may be used in scenarios other than the protection of a noise-sensitive device from interference from a collocated antenna. Rather, the on-chip EMI shielding may be used in any scenario where a noise-sensitive device needs to be shielded from EMI, regardless of the source of the EMI.

Further, as would be apparent to one of ordinary skill in the art, the foregoing on-chip EMI shielding examples may not include every component of an RFIC. Rather, for clarity, certain components may be omitted.

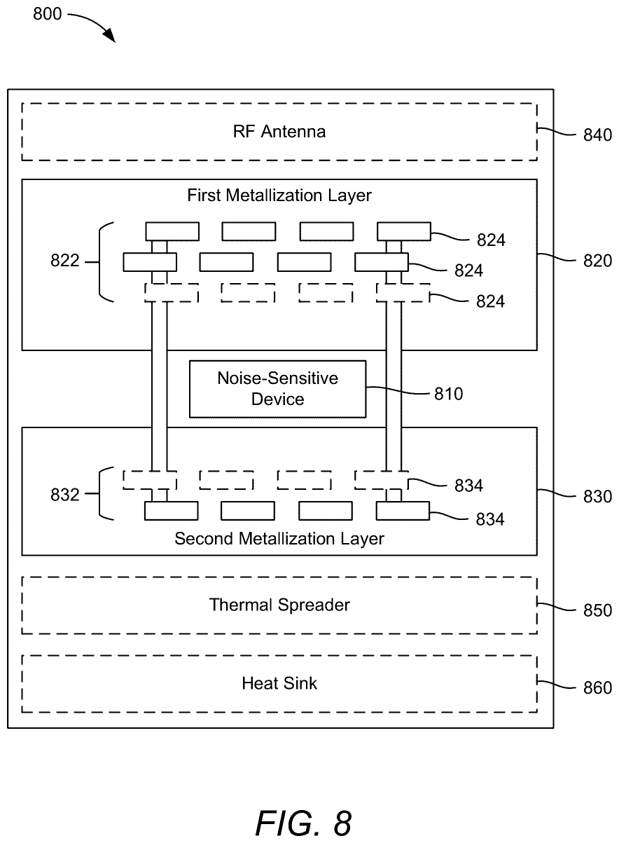

FIG. 8 illustrates a cross section of an example integrated circuit 800, according to aspects of the disclosure. The integrated circuit 800 further includes a noise-sensitive device 810, such as an LNA or a PA. The integrated circuit 800 further includes a first metallization layer 820 (e.g., a front-side BEOL layer) disposed on a first side (e.g., top side) of the noise-sensitive device 810, wherein the first metallization layer 820 includes a plurality of conductive routing layers 822, and wherein conductive routing 824 within the plurality of conductive routing layers 822 is configured as a first side of an on-chip EMI shield around the first side of the noise-sensitive device 810.

The integrated circuit 800 further includes a second metallization layer 830 (e.g., a back-side BEOL layer or an interposer layer) disposed on a second side (e.g., bottom side) of the noise-sensitive device 810 opposite the first side of the noise-sensitive device 810, wherein the second metallization layer 830 includes one or more conductive routing layers 832, wherein conductive routing 834 within the one or more conductive routing layers 832 is configured as a second side of the on-chip EMI shield around the second side of the noise-sensitive device 810, and wherein the conductive routing 834 within the one or more conductive routing layers 832 is coupled to the conductive routing 824 within the plurality of conductive routing layers 822 (e.g., via a back side contact).

In an aspect, a layer of the plurality of conductive routing layers 822 furthest from the noise-sensitive device 810 is configured as a first ground plane for the first side of the on-chip EMI shield, and a layer of the one or more conductive routing layers 832 furthest from the noise-sensitive device 810 is configured as a second ground plane for the second side of the on-chip EMI shield.

In an aspect, the conductive routing 824 within each of the plurality of conductive routing layers 822 is configured as a conductive mesh, and the conductive routing 834 within each of the plurality of conductive routing layers 832 is configured as a conductive mesh.

In an aspect, the conductive routing 824 within each of the plurality of conductive routing layers 822 is offset from a successive layer of the plurality of conductive routing layers 822, and the conductive routing 834 within each of the one or more conductive routing layers 832 is offset from a successive layer of the plurality of conductive routing layers 832.

In an aspect, the integrated circuit 800 optionally comprises a radio frequency (RF) antenna 840 disposed on a side of the first metallization layer 820 opposite the second metallization layer 830.

In an aspect, the integrated circuit 800 optionally comprises a thermal spreader 850 coupled to the second metallization layer 830 or a heat sink 860 coupled to the second metallization layer 830.

In the example of FIG. 8, spaces between the various blocks, such as the first metallization layer 820 and the second metallization layer 830, indicate that other layers or components may be present between the illustrated layers. For example, there may be a hybrid bond, a substrate, a BSRDL, and/or the like between the first metallization layer 820 and the second metallization layer 830. Similarly, as another example, there may be a substrate between the optional RF antenna 840 and the first metallization layer 820.

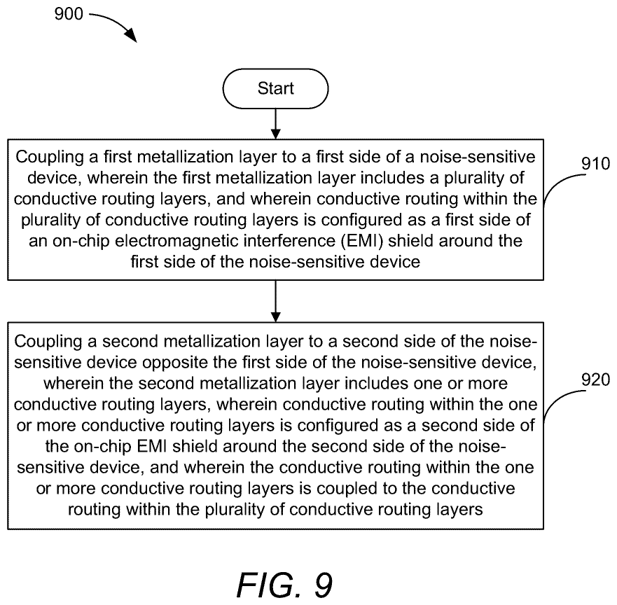

FIG. 9 illustrates an example method 900 of manufacturing an integrated circuit, according to aspects of the disclosure. The method 900 may be performed by various manufacturing machinery, as is known in the art. The method 900 may also be stored as instructions on a (non-transitory) computer-readable medium, where the various manufacturing machinery execute the stored instructions to perform the method 900.

An operation 910 of method 900 comprises connecting a first metallization layer (e.g., first metallization layer 820) to a first side of a noise-sensitive device (e.g., noise-sensitive device 810), wherein the first metallization layer includes a plurality of conductive routing layers (e.g., conductive routing layers 822), and wherein conductive routing (e.g., conductive routing 824) within the plurality of conductive routing layers is configured as a first side of an on-chip EMI shield around the first side of the noise-sensitive device.

An operation 920 of method 900 comprises connecting a second metallization layer (e.g., second metallization layer 830) to a second side of the noise-sensitive device opposite the first side of the noise-sensitive device, wherein the second metallization layer includes one or more conductive routing layers (e.g., conductive routing layers 832), wherein conductive routing (e.g., conductive routing 834) within the one or more conductive routing layers is configured as a second side of the on-chip EMI shield around the second side of the noise-sensitive device, and wherein the conductive routing within the one or more conductive routing layers is coupled to the conductive routing within the plurality of conductive routing layers.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An integrated circuit, comprising: a noise-sensitive device; a first metallization layer disposed on a first side of the noise-sensitive device, wherein the first metallization layer includes a plurality of conductive routing layers, and wherein conductive routing within the plurality of conductive routing layers is configured as a first side of an on-chip electromagnetic interference (EMI) shield around the first side of the noise-sensitive device; and a second metallization layer disposed on a second side of the noise-sensitive device opposite the first side of the noise-sensitive device, wherein the second metallization layer includes one or more conductive routing layers, wherein conductive routing within the one or more conductive routing layers is configured as a second side of the on-chip EMI shield around the second side of the noise-sensitive device, and wherein the conductive routing within the one or more conductive routing layers is coupled to the conductive routing within the plurality of conductive routing layers.

Clause 2. The integrated circuit of clause 1, wherein: a layer of the plurality of conductive routing layers furthest from the noise-sensitive device is configured as a first ground plane for the first side of the on-chip EMI shield, and a layer of the one or more conductive routing layers furthest from the noise-sensitive device is configured as a second ground plane for the second side of the on-chip EMI shield.

Clause 3. The integrated circuit of any of clauses 1 to 2, wherein the conductive routing within the plurality of conductive routing layers comprises: a first layer of the plurality of conductive routing layers being configured as a ground plane for the first side of the on-chip EMI shield, and conductive routing within intermediate layers of the plurality of conductive routing layers between the first layer and the first side of the noise-sensitive device being interconnected to each other and to the ground plane.

Clause 4. The integrated circuit of any of clauses 1 to 3, wherein: the conductive routing within each of the plurality of conductive routing layers is configured as a conductive mesh, and the conductive routing within each of the one or more conductive routing layers is configured as a conductive mesh.

Clause 5. The integrated circuit of any of clauses 1 to 4, wherein: the conductive routing within each of the plurality of conductive routing layers is offset from a successive layer of the plurality of conductive routing layers, and the conductive routing within each of the one or more conductive routing layers is offset from a successive layer of the one or more conductive routing layers.

Clause 6. The integrated circuit of any of clauses 1 to 5, wherein the first metallization layer comprises a front-side back end of line (BEOL) layer.

Clause 7. The integrated circuit of any of clauses 1 to 6, wherein: the second metallization layer comprises a back-side BEOL layer, and the one or more conductive routing layers comprise a second plurality of conductive routing layers.

Clause 8. The integrated circuit of clause 7, wherein conductive routing within the second plurality of conductive routing layers comprises: a first layer of the second plurality of conductive routing layers being configured as a ground plane for the second side of the on-chip EMI shield, and conductive routing within intermediate layers of the second plurality of conductive routing layers between the first layer and the second side of the noise-sensitive device being interconnected to each other and to the ground plane.

Clause 9. The integrated circuit of any of clauses 1 to 6, wherein the second metallization layer comprises an interposer layer.

Clause 10. The integrated circuit of clause 9, further comprising: a hybrid bond between the first metallization layer and the interposer layer.

Clause 11. The integrated circuit of any of clauses 9 to 10, further comprising: a thermal spreader coupled to the interposer layer, or a heat sink coupled to the interposer layer.

Clause 12. The integrated circuit of any of clauses 1 to 11, further comprising: a radio frequency (RF) antenna disposed on a side of the first metallization layer opposite the second metallization layer.

Clause 13. The integrated circuit of clause 12, wherein: the conductive routing within the plurality of conductive routing layers comprises a first plurality of conductive segments, the conductive routing within the one or more conductive routing layers comprises a second plurality of conductive segments, and a size of spacing among the first plurality of conductive segments and the second plurality of conductive segments is based on a wavelength of a frequency band at which the RF antenna operates.

Clause 14. The integrated circuit of any of clauses 12 to 13, further comprising: a substrate between the RF antenna and the first metallization layer; and one or more through silicon vias (TSVs) connecting the RF antenna to the first metallization layer.

Clause 15. The integrated circuit of any of clauses 1 to 14, wherein the noise-sensitive device comprises: a low noise amplifier, or a power amplifier.

Clause 16. The integrated circuit of any of clauses 1 to 15, further comprising: a second noise-sensitive device, wherein the conductive routing within the plurality of conductive routing layers is further configured as a first side of a second on-chip EMI shield around a first side of the second noise-sensitive device, and wherein the conductive routing within the one or more conductive routing layers is further configured as a second side of the second on-chip EMI shield around a second side of the second noise-sensitive device.

Clause 17. A method of manufacturing an integrated circuit, comprising: coupling a first metallization layer to a first side of a noise-sensitive device, wherein the first metallization layer includes a plurality of conductive routing layers, and wherein conductive routing within the plurality of conductive routing layers is configured as a first side of an on-chip electromagnetic interference (EMI) shield around the first side of the noise-sensitive device; and coupling a second metallization layer to a second side of the noise-sensitive device opposite the first side of the noise-sensitive device, wherein the second metallization layer includes one or more conductive routing layers, wherein conductive routing within the one or more conductive routing layers is configured as a second side of the on-chip EMI shield around the second side of the noise-sensitive device, and wherein the conductive routing within the one or more conductive routing layers is coupled to the conductive routing within the plurality of conductive routing layers.

Clause 18. The method of clause 17, wherein: a layer of the plurality of conductive routing layers furthest from the noise-sensitive device is configured as a first ground plane for the first side of the on-chip EMI shield, and a layer of the one or more conductive routing layers furthest from the noise-sensitive device is configured as a second ground plane for the second side of the on-chip EMI shield.

Clause 19. The method of any of clauses 17 to 18, wherein the conductive routing within the plurality of conductive routing layers comprises: a first layer of the plurality of conductive routing layers being configured as a ground plane for the first side of the on-chip EMI shield, and conductive routing within intermediate layers of the plurality of conductive routing layers between the first layer and the first side of the noise-sensitive device being interconnected to each other and to the ground plane.

Clause 20. The method of any of clauses 17 to 19, wherein: the conductive routing within each of the plurality of conductive routing layers is configured as a conductive mesh, and the conductive routing within each of the one or more conductive routing layers is configured as a conductive mesh.

Clause 21. The method of any of clauses 17 to 20, wherein: the conductive routing within each of the plurality of conductive routing layers is offset from a successive layer of the plurality of conductive routing layers, and the conductive routing within each of the one or more conductive routing layers is offset from a successive layer of the one or more conductive routing layers.

Clause 22. The method of any of clauses 17 to 21, wherein the first metallization layer comprises a front-side back end of line (BEOL) layer.

Clause 23. The method of any of clauses 17 to 22, wherein: the second metallization layer comprises a back-side BEOL layer, and the one or more conductive routing layers comprise a second plurality of conductive routing layers.

Clause 24. The method of clause 23, wherein conductive routing within the second plurality of conductive routing layers comprises: a first layer of the second plurality of conductive routing layers being configured as a ground plane for the second side of the on-chip EMI shield, and conductive routing within intermediate layers of the second plurality of conductive routing layers between the first layer and the second side of the noise-sensitive device being interconnected to each other and to the ground plane.

Clause 25. The method of any of clauses 17 to 22, wherein the second metallization layer comprises an interposer layer.

Clause 26. The method of clause 25, further comprising: applying a hybrid bond between the first metallization layer and the interposer layer.

Clause 27. The method of any of clauses 25 to 26, further comprising: coupling a thermal spreader to the interposer layer; or coupling a heat sink to the interposer layer.

Clause 28. The method of any of clauses 17 to 27, further comprising: coupling a radio frequency (RF) antenna to a side of the first metallization layer opposite the second metallization layer.

Clause 29. The method of clause 28, wherein: the conductive routing within the plurality of conductive routing layers comprises a first plurality of conductive segments, the conductive routing within the one or more conductive routing layers comprises a second plurality of conductive segments, and a size of spacing among the first plurality of conductive segments and the second plurality of conductive segments is based on a wavelength of a frequency band at which the RF antenna operates.

Clause 30. The method of any of clauses 28 to 29, further comprising: providing a substrate between the RF antenna and the first metallization layer; and providing one or more through silicon vias (TSVs) connecting the RF antenna to the first metallization layer.

Clause 31. The method of any of clauses 17 to 30, wherein the noise-sensitive device comprises: a low noise amplifier, or a power amplifier.

Clause 32. The method of any of clauses 17 to 31, further comprising: coupling a second noise-sensitive device to the first metallization layer and the second metallization layer, wherein the conductive routing within the plurality of conductive routing layers is further configured as a first side of a second on-chip EMI shield around a first side of the second noise-sensitive device, and wherein the conductive routing within the one or more conductive routing layers is further configured as a second side of the second on-chip EMI shield around a second side of the second noise-sensitive device.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An integrated circuit, comprising:
a noise-sensitive device;
a first metallization layer disposed on a first side of the noise-sensitive device, wherein the first metallization layer includes a plurality of conductive routing layers, and wherein conductive routing within the plurality of conductive routing layers is configured as a first side of an on-chip electromagnetic interference (EMI) shield around the first side of the noise-sensitive device; and
a second metallization layer disposed on a second side of the noise-sensitive device opposite the first side of the noise-sensitive device, wherein the second metallization layer includes one or more conductive routing layers, wherein conductive routing within the one or more conductive routing layers is configured as a second side of the on-chip EMI shield around the second side of the noise-sensitive device, and wherein the conductive routing within the one or more conductive routing layers is coupled to the conductive routing within the plurality of conductive routing layers.

2. The integrated circuit of claim 1, wherein:
a layer of the plurality of conductive routing layers furthest from the noise-sensitive device is configured as a first ground plane for the first side of the on-chip EMI shield, and
a layer of the one or more conductive routing layers furthest from the noise-sensitive device is configured as a second ground plane for the second side of the on-chip EMI shield.

3. The integrated circuit of claim 1, wherein the conductive routing within the plurality of conductive routing layers comprises:
a first layer of the plurality of conductive routing layers being configured as a ground plane for the first side of the on-chip EMI shield, and
conductive routing within intermediate layers of the plurality of conductive routing layers between the first layer and the first side of the noise-sensitive device being interconnected to each other and to the ground plane.

4. The integrated circuit of claim 1, wherein:
the conductive routing within each of the plurality of conductive routing layers is configured as a conductive mesh, and
the conductive routing within each of the one or more conductive routing layers is configured as a conductive mesh.

5. The integrated circuit of claim 1, wherein:
the conductive routing within each of the plurality of conductive routing layers is offset from a successive layer of the plurality of conductive routing layers, and
the conductive routing within each of the one or more conductive routing layers is offset from a successive layer of the one or more conductive routing layers.

6. The integrated circuit of claim 1, wherein the first metallization layer comprises a front-side back end of line (BEOL) layer.

7. The integrated circuit of claim 1, wherein:
the second metallization layer comprises a back-side BEOL layer, and
the one or more conductive routing layers comprise a second plurality of conductive routing layers.

8. The integrated circuit of claim 7, wherein conductive routing within the second plurality of conductive routing layers comprises:
a first layer of the second plurality of conductive routing layers being configured as a ground plane for the second side of the on-chip EMI shield, and
conductive routing within intermediate layers of the second plurality of conductive routing layers between the first layer and the second side of the noise-sensitive device being interconnected to each other and to the ground plane.

9. The integrated circuit of claim 1, wherein the second metallization layer comprises an interposer layer.

10. The integrated circuit of claim 9, further comprising:
a hybrid bond between the first metallization layer and the interposer layer.

11. The integrated circuit of claim 9, further comprising:
a thermal spreader coupled to the interposer layer, or
a heat sink coupled to the interposer layer.

12. The integrated circuit of claim 1, further comprising:
a radio frequency (RF) antenna disposed on a side of the first metallization layer opposite the second metallization layer.

13. The integrated circuit of claim 12, wherein:
the conductive routing within the plurality of conductive routing layers comprises a first plurality of conductive segments,
the conductive routing within the one or more conductive routing layers comprises a second plurality of conductive segments, and
a size of spacing among the first plurality of conductive segments and the second plurality of conductive segments is based on a wavelength of a frequency band at which the RF antenna operates.

14. The integrated circuit of claim 12, further comprising:
a substrate between the RF antenna and the first metallization layer; and
one or more through silicon vias (TSVs) connecting the RF antenna to the first metallization layer.

15. The integrated circuit of claim 1, wherein the noise-sensitive device comprises:
a low noise amplifier, or
a power amplifier.

16. The integrated circuit of claim 1, further comprising:
a second noise-sensitive device,
wherein the conductive routing within the plurality of conductive routing layers is further configured as a first side of a second on-chip EMI shield around a first side of the second noise-sensitive device, and
wherein the conductive routing within the one or more conductive routing layers is further configured as a second side of the second on-chip EMI shield around a second side of the second noise-sensitive device.

17. A method of manufacturing an integrated circuit, comprising:
coupling a first metallization layer to a first side of a noise-sensitive device, wherein the first metallization layer includes a plurality of conductive routing layers, and wherein conductive routing within the plurality of conductive routing layers is configured as a first side of an on-chip electromagnetic interference (EMI) shield around the first side of the noise-sensitive device; and
coupling a second metallization layer to a second side of the noise-sensitive device opposite the first side of the noise-sensitive device, wherein the second metallization layer includes one or more conductive routing layers, wherein conductive routing within the one or more conductive routing layers is configured as a second side of the on-chip EMI shield around the second side of the noise-sensitive device, and wherein the conductive routing within the one or more conductive routing layers is coupled to the conductive routing within the plurality of conductive routing layers.

18. The method of claim 17, wherein:
a layer of the plurality of conductive routing layers furthest from the noise-sensitive device is configured as a first ground plane for the first side of the on-chip EMI shield, and
a layer of the one or more conductive routing layers furthest from the noise-sensitive device is configured as a second ground plane for the second side of the on-chip EMI shield.

19. The method of claim 17, wherein the conductive routing within the plurality of conductive routing layers comprises:
a first layer of the plurality of conductive routing layers being configured as a ground plane for the first side of the on-chip EMI shield, and
conductive routing within intermediate layers of the plurality of conductive routing layers between the first layer and the first side of the noise-sensitive device being interconnected to each other and to the ground plane.

20. The method of claim 17, wherein:
the conductive routing within each of the plurality of conductive routing layers is configured as a conductive mesh, and
the conductive routing within each of the one or more conductive routing layers is configured as a conductive mesh.

21. The method of claim 17, wherein:
the conductive routing within each of the plurality of conductive routing layers is offset from a successive layer of the plurality of conductive routing layers, and
the conductive routing within each of the one or more conductive routing layers is offset from a successive layer of the one or more conductive routing layers.

22. The method of claim 17, wherein the first metallization layer comprises a front-side back end of line (BEOL) layer.

23. The method of claim 17, wherein:
the second metallization layer comprises a back-side BEOL layer, and
the one or more conductive routing layers comprise a second plurality of conductive routing layers.

24. The method of claim 23, wherein conductive routing within the second plurality of conductive routing layers comprises:
a first layer of the second plurality of conductive routing layers being configured as a ground plane for the second side of the on-chip EMI shield, and
conductive routing within intermediate layers of the second plurality of conductive routing layers between the first layer and the second side of the noise-sensitive device being interconnected to each other and to the ground plane.

25. The method of claim 17, wherein the second metallization layer comprises an interposer layer.

26. The method of claim 25, further comprising:
applying a hybrid bond between the first metallization layer and the interposer layer.

27. The method of claim 25, further comprising:
coupling a thermal spreader to the interposer layer; or
coupling a heat sink to the interposer layer.

28. The method of claim 17, further comprising:
coupling a radio frequency (RF) antenna to a side of the first metallization layer opposite the second metallization layer.

29. The method of claim 28, wherein:
the conductive routing within the plurality of conductive routing layers comprises a first plurality of conductive segments,
the conductive routing within the one or more conductive routing layers comprises a second plurality of conductive segments, and
a size of spacing among the first plurality of conductive segments and the second plurality of conductive segments is based on a wavelength of a frequency band at which the RF antenna operates.

30. The method of claim 28, further comprising:
providing a substrate between the RF antenna and the first metallization layer; and
providing one or more through silicon vias (TSVs) connecting the RF antenna to the first metallization layer.

31. The method of claim 17, wherein the noise-sensitive device comprises:
a low noise amplifier, or
a power amplifier.

32. The method of claim 17, further comprising:
coupling a second noise-sensitive device to the first metallization layer and the second metallization layer,
wherein the conductive routing within the plurality of conductive routing layers is further configured as a first side of a second on-chip EMI shield around a first side of the second noise-sensitive device, and
wherein the conductive routing within the one or more conductive routing layers is further configured as a second side of the second on-chip EMI shield around a second side of the second noise-sensitive device.
